(19) United States
(12) Patent Application Publication
(10) Pub. No.: US 2015/0223363 A1
(43) Pub. Date: Aug. 6, 2015

(54) Multimodule

(71) Applicant: Hitachi Metals, Ltd., Tokyo (JP)

(72) Inventor: Yoshinori SUNAGA, Hitachinaka (JP)

(21) Appl. No.: 14/589,018

(22) Filed: Jan. 5, 2015

(30) Foreign Application Priority Data
Feb. 6, 2014 (JP) 2014-021000

(51) Int. Cl. H05K 7/14; H05K 7/20

(52) U.S. Cl. CPC H05K 7/1487; H05K 7/20709; H05K 7/20409

(57) ABSTRACT

A plurality of modules is densely arranged in a small space, and degradation of high-speed digital signals transmitted between these modules is suppressed. A chassis to which a power cable and an optical signal cable are drawn is provided, and a plurality of first modules which are mounted on the chassis and which are connected to the power cable and the optical signal cable are provided. Each first module includes: a first metal package; a first package substrate accommodated in the first metal package and thermally connected to the first metal package; and a first semiconductor chip equipped on the first package substrate, and the chassis and the first metal package included in each first module are thermally connected to each other.

### CROSS-REFERENCE TO RELATED APPLICATION

The present application claims priority from Japanese Patent Application No. 2014-021000 filed on Feb. 6, 2014, the content of which is hereby incorporated by reference into this application.

### TECHNICAL FIELD OF THE INVENTION

The present invention relates to a multimodule having a plurality of modules mounted on a common support member.

### BACKGROUND OF THE INVENTION

Computers, servers, network equipment, etc. have a printed circuit board generally called a “mother board”, and a plurality of modules (a communication module, a memory module, a storage module, etc.) are mounted on this mother board. Each module has a substrate called a “module board” or a “package board”, and a semiconductor chip (a memory chip, a controller chip to control the memory chip, and others) used for various purposes is equipped directly or via an interposer on this board. That is, the semiconductor chip provided in each module is connected with the mother board via the package board, and then, is connected with other module on this mother board via the mother board or a module provided in other device. In the following explanation, the board on which the semiconductor chip is equipped directly or via the interposer is generically called a “package board”.

Here, the throughput of the semiconductor chip used for various modules has been rapidly improved in accordance with a line-thinning technique of the semiconductor manufacturing process. In addition, a high-speed technique of the signal inputted into and outputted from the semiconductor chip has been also advanced every year in accordance with the improvement of the throughput of the semiconductor chip, and it is expected that the speed of signals inputted into and outputted from a next-generation semiconductor chip is 25 Gbit/sec, and that the speed of signals inputted into and outputted from a more-advanced-generation semiconductor chip is 50 Gbit/sec.

### PRIOR ART DOCUMENT

### Patent Document

Patent Document 1: Japanese Patent Application Laid-Open Publication No. 2007-329910

### SUMMARY OF THE INVENTION

While the speed of the signals inputted into and outputted from the semiconductor chip increases, an amount of loss of the high-speed digital signals in electric wiring is large. Therefore, in the conventional system in which a plurality of modules mounted on the mother board are connected to each other via the electric wiring formed on the mother board, a large loss is generated in the high-speed digital signals transmitted between the modules. For example, when the signal speed is about 25 Gbit/sec, the loss of about 0.8 dB/cm is generated on the electric wiring formed on a general mother board (printed circuit board). Moreover, even on the electric wiring formed on the high-class printed circuit board for high speed signals, the loss of about 0.4 dB/cm is generated. Therefore, since a signal waveform greatly deteriorates even if a transmission distance is relatively short (for example, 30 cm), a circuit for compensating the signal deterioration is required.

However, the circuit for compensating the signal deterioration has large power consumption, and has become a major factor of increase in power consumption of a computer, a server, network equipment, etc.

An object of the present invention is to densely arrange a plurality of modules in a small space, and besides, to suppress degradation of high-speed digital signals transmitted between these modules.

The multimodule according to the present invention includes: a support member to which a power cable and an optical signal cable are drawn; and a plurality of first modules mounted on the support member and to which the power cable and an optical signal cable are connected. Each of the first modules includes: a first package; a first package substrate accommodated in the first package; and a first semiconductor chip equipped on the first package substrate.

In one aspect of the multimodule of the present invention, a plurality of second modules mounted so as to be overlaid on each of the first modules are provided. Each of the second modules includes: a second package; a second package substrate accommodated in the second package; and a second semiconductor chip equipped on the second package substrate.

In another aspect of the multimodule of the present invention, the first package and the second package are made of metal, and are thermally connected to each other. Moreover, the first package and the first package substrate accommodated in the first package are thermally connected, and the second package and the second package substrate accommodated in the second package are thermally connected.

In another aspect of the multimodule of the present invention, the first package substrate accommodated in the first package and the second package substrate accommodated in the second package are electrically connected.

In still another aspect of the multimodule of the present invention, each of the first modules includes: a power supply submodule and an optical submodule mounted on one surface of the first package substrate; a controller chip as the first semiconductor chip equipped on the other surface of the first package substrate; and a first electric connector arranged on the other surface of the first package substrate. Moreover, each of the second modules includes: a second electric connector arranged on one surface of the second package substrate; and a memory chip as the second semiconductor chip equipped on the other surface of the second package substrate. In the first module, via the wiring formed in the first package substrate, the optical submodule and the controller chip, and the first electric connector and the controller chip are connected to each other. Moreover, in the second module, via the wiring formed on the second package substrate, the memory chip and the second electric connector are connected. Besides, via the first electric connector and the second electric connector, the first module and the second module are connected.

In still another aspect of the multimodule of the present invention, a passage is formed in each of the support member, the first package, and the second package for communicating with each other.

In still another aspect of the multimodule of the present invention, a heat conduction member penetrating the support member, the first package and the second package are provided, and a radiating fin is provided in at least part of the heat conduction members.

In still another aspect of the multimodule of the present invention, a third module mounted so as to be overlaid on the second module is provided. The third module includes: a third package; a third package substrate accommodated in the third package; and a third semiconductor chip equipped in the third package substrate.

In still another aspect of the multimodule of the present invention, on the second package substrate of the second module, a volatile memory chip as the second semiconductor chip is equipped. On the other hand, on the third package substrate of the third module, a nonvolatile memory chip as the third semiconductor chip is equipped.

In still another aspect of the multimodule of the present invention, the support member includes a plurality of mounting portions on which the first module is mounted, the mounting portions being rotatably connected with each other.

According to the present invention, a plurality of modules are densely arranged in a small space, and besides, degradation of the high-speed digital signals transmitted between these modules is suppressed.

### BRIEF DESCRIPTIONS OF THE DRAWINGS

FIG. 1A is a plane view of a multimodule according to a first embodiment;

FIG. 1B is a side view of the multimodule according to the first embodiment;

FIG. 2 is a cross-sectional view showing a structure of a chassis and a processor module shown in FIG. 1;

FIG. 3 is a schematic perspective view of the chassis and the processor module shown in FIG. 1;

FIG. 4 is a cross-sectional taken along a line A-A shown in FIG. 2;

FIG. 5A is a plane view of a multimodule according to a second embodiment;

FIG. 5B is a side view of the multimodule according to the second embodiment;

FIG. 6 is a cross-sectional view showing a structure of a chassis, a processor module, and a memory module shown in FIG. 5;

FIG. 7 is a plane view showing an expanded state of the chassis shown in FIG. 5;

FIG. 8 is a cross-sectional view showing a structure of a chassis, a processor module, and a memory module included in a multimodule according to a third embodiment; and

FIG. 9 is a cross-sectional view showing a structure of a chassis, a processor module, a memory module, and a storage module included in a multimodule according to a fourth embodiment.

### DESCRIPTIONS OF THE PREFERRED EMBODIMENTS

### First Embodiment

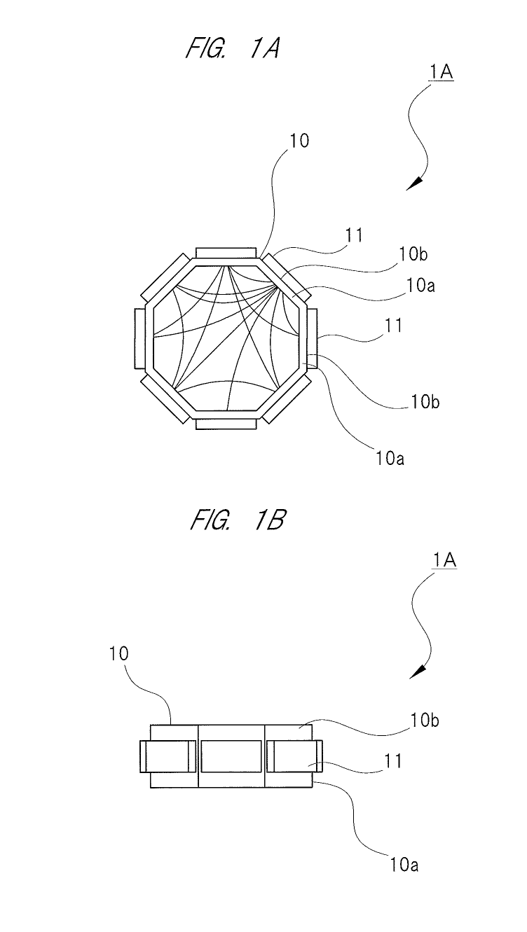

Hereafter, one example of the embodiment of the present invention will be described in detail with reference to the drawings. A multimodule 1A shown in FIG. 1 includes a chassis 10 as a support member, and a plurality of first modules 11 mounted on the chassis 10.

The chassis 10 is formed with a bent metal plate (for example, having a thickness of 2 mm) and has an octagonal cross-sectional shape. That is, the chassis 10 has eight side walls 10a, and the first module 11 is mounted on each of these side walls 10a. That is, in this embodiment, each side wall 10a of the chassis 10 is a mounting portion on which the first module 11 is mounted.

In the present embodiment, one first module 11 is mounted on an outer surface of the eight side walls 10a of the chassis 10. That is, the multimodule 1A is provided with eight first modules 11. These first module 11 are suitably connected with each other via a cable inside the chassis 10. In the following explanation, the outer surface of the side wall 10a of the chassis 10 on which the first module 11 is mounted is called “a mounting surface 10b” in some cases.

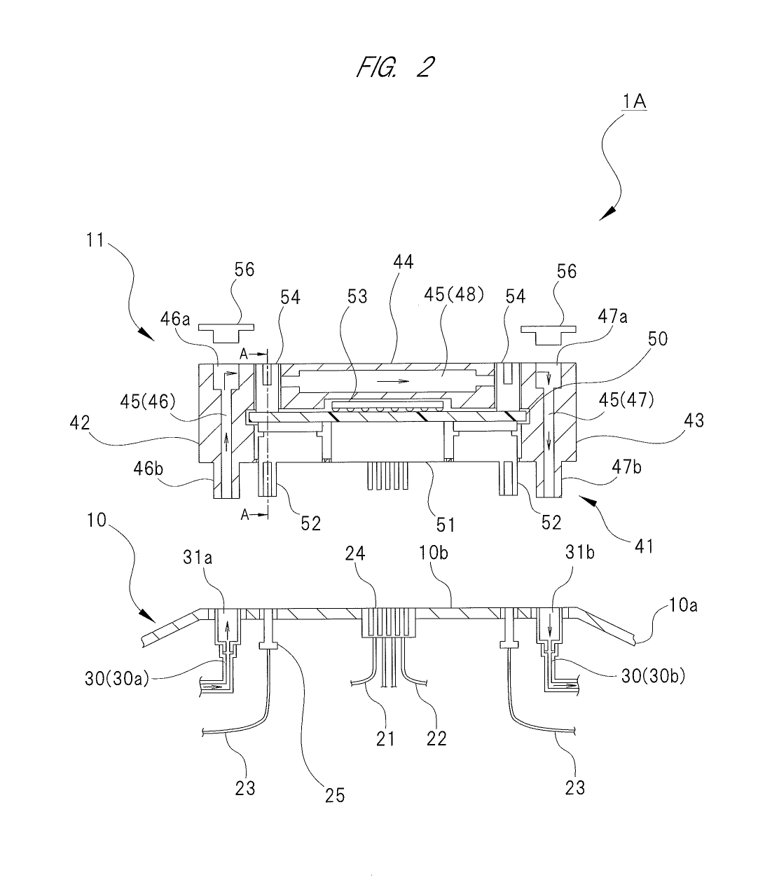

As shown in FIG. 2, a plurality of cables are drawn in the chassis 10. Specifically, at least a power cable 21, an electric signal cable 22, and an optical signal cable 23 are drawn into the chassis 10. The power cable 21 is a cable to supply electric power, the electric signal cable 22 is a cable for low-speed signals (for example, 1 Gbit/sec or less), and the optical signal cable 23 is a cable for high-speed signals (for example, 25 Gbit/sec).

The power cable 21 and the electric signal cable 22 are collectively connected to a common electric connector 24 together. On the other hand, the end of each optical signal cable 23 is equipped with an optical connector 25. Each optical signal cable 23 is a multicore cable in which a plurality of optical fibers are embedded, and the optical connector 25 is an MT (Mechanically Transferable) connector to collectively connect the plurality of optical fibers embedded in the optical signal cable 23.

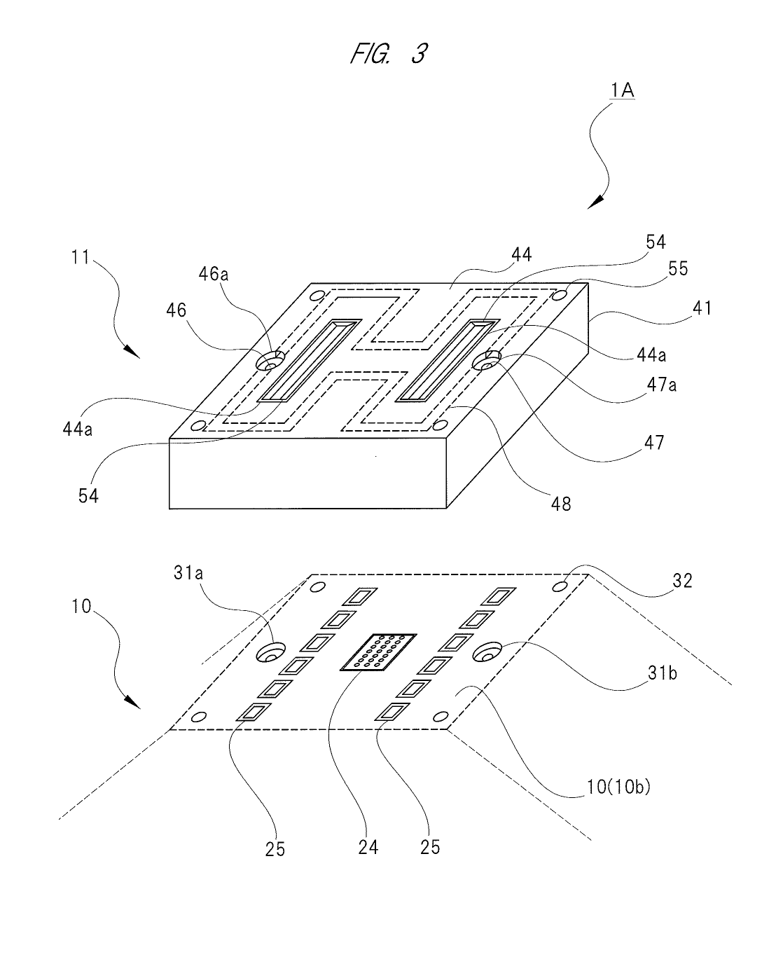

As shown in FIG. 3, the electric connector 24 is arranged in substantially the center of the mounting surface 10b, and a plurality of optical connectors 25 are arranged in one line on both sides of this electric connector 24. That is, two optical connector lines opposed to each other so as to interpose the electric connector 24 therebetween are located on the mounting surface 10b.

A plurality of opening portions for placing the electric connector 24 and the optical connector 25 therein are formed on the side wall 10a (FIG. 2) of the chassis 10, and the electric connector 24 and the optical connector 25 are fitted into the predetermined opening portions and are fixed to the side wall 10a. Of course, the electric connector 24 and the optical connector 25 are detachable to the side wall 10a, i.e., the chassis 10, if needed.

As shown in FIG. 2, inside the chassis 10, a passage 30a for supplying cooling water to the first module 11 and a passage 30b for collecting the cooling water which has passed through the first module 11 are formed. In the following explanation, the passage 30a is called “a feed passage 30a”, and the passage 30b is called “a return passage 30b”. The feed passage 30a and the return passage 30b are collectively called “a passage 30”. Although not shown in the drawings, the feed passage 30a and the return passage 30b communicate with each other to forma continued passage, and a tank for storing the cooling water and a pump for circulating the cooling water are provided on this passage. Of course, the feed passage 30a and the return passage 30b are drawn out of the chassis 10 to connect with a tank and a pump set outside of the chassis 10. Moreover, although the feed passage 30a and the return passage 30b in the present embodiment are formed of a pipe, the feed passage 30a and the return passage 30b may be formed of a rubber tube with flexibility or others.

As shown in FIG. 2, one end of the feed passage 30a is connected to a mouth ring 31a fixed to the side wall 10a of the chassis 10. Similarly, one end of the return passage 30b is connected to a mouth ring 31b fixed to the side wall 10a of the chassis 10. As shown in FIG. 3, a through bore 32 penetrating through the side wall 10a (FIG. 2) is formed at each of four corners of each mounting surface 10b.

As shown in FIG. 3, the first module 11 is provided with a block-shaped first package 41. The first package 41 in the present embodiment is made of metal. Therefore, in the following explanation, the first package 41 is called “a first metal package 41”.

The first metal package 41 is formed into a predetermined shape by a die casting method or a cutting method so as to have a left side wall 42, a right side wall 43, and a ceiling 44 shown in FIG. 2. A continued passage 45 is formed inside the left side wall 42, the right side wall 43, and the ceiling 44. Specifically, a first perpendicular passage 46 penetrating through the left side wall 42 is formed inside the left side wall 42, a second perpendicular passage 47 penetrating through the right side wall 43 is formed inside the right side wall 43, and a first horizontal passage 48 penetrating through the ceiling 44 is formed inside the ceiling 44. One end of the first perpendicular passage 46 is expanded in diameter to form a connecting hole 46a that is opened on an upper end surface of the side wall 42, and the other end of the first perpendicular passage 46 is protruded from a lower end surface of the left side wall 42 to form a pipe joint 46b. Moreover, one end of the second perpendicular passage 47 is expanded in diameter to forma connecting hole 47a that is opened on an upper end surface of the right side wall 43, and the other end of the second perpendicular passage 47 is protruded from a lower end surface of the right side wall 43 to form a pipe joint 47b. Besides, one end of the first horizontal passage 48 is opened on one side surface of the ceiling 44, and the other end thereof is opened on the other side surface of the ceiling 44. In addition, the first perpendicular passage 46 and the second perpendicular passage 47 are connected via the first horizontal passage 48 to communicate with each other. That is, the continued passage 45 is formed inside the first metal package 41 by the first perpendicular passage 46, the second perpendicular passage 47, and the first horizontal passage 48.

As shown in FIG. 2, a first package substrate 50 is accommodated inside the first metal package 41. The first metal package 41 and the first package substrate 50 are physically in contact with each other, and thermally connected to each other. Specifically, a peripheral edge portion of the first package substrate 50 is fitted into a retention groove formed on an inner surface of the first metal package 41. A power supply submodule 51 and a plurality of optical submodules 52 are mounted on one surface (lower surface) of the first package substrate 50 accommodated in the first metal package 41. The power supply submodule 51 and the optical submodule 52 are arranged at positions corresponding to the electric connector 24 and the optical connector 25 provided in the chassis 10, respectively. Specifically, the power supply submodule 51 is arranged in the center of the lower surface of the first package substrate 50, and a plurality of optical submodules 52 are arranged in one line on both sides of this power supply submodule 51. That is, two optical submodule lines opposed to each other so as to interpose the power supply submodule 51 therebetween are located on the lower surface of the first package substrate 50.

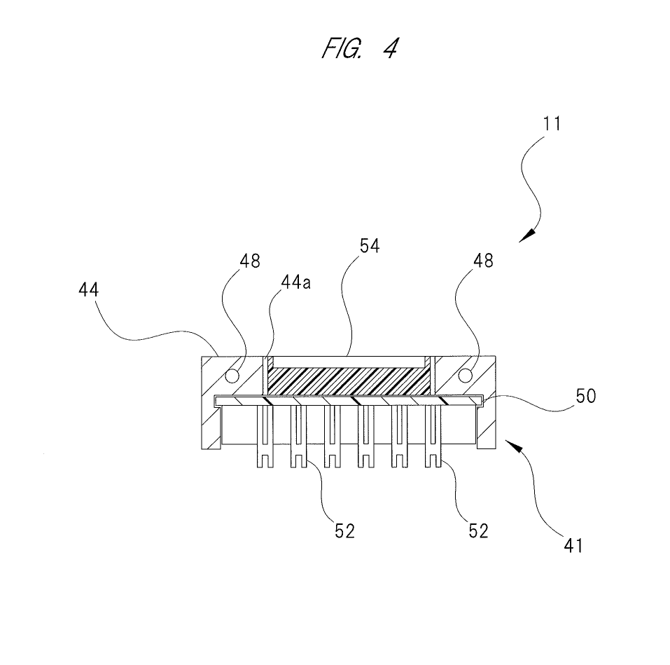

A first semiconductor chip 53 is equipped (flip chip mounting) on the other surface (upper surface) of the first package substrate 50, and a pair of first electric connectors (receptacle connector) 54 are mounted on both sides of the first semiconductor chip 53. The first semiconductor chip 53 and the optical submodule 52, and the first semiconductor chip 53 and the receptacle connector 54 are electrically connected via wiring or/and a through hole formed on the first package substrate 50. As shown in FIGS. 3 and 4, a slit 44a is formed on the ceiling 44 of the first metal package 41, and the receptacle connector 54 is exposed to the upper surface of the first module 11. Moreover, the first horizontal passage 48 formed on the ceiling 44 of the first metal package 41 winds so as to avoid the receptacle connector 54, and communicates the first perpendicular passage 46 to the second perpendicular passage 47. Besides, as shown in FIG. 3, a through bore 55 penetrating through the first metal package 41 is formed at each of four corners of the first metal package 41.

Here, the first semiconductor chip 53 shown in FIG. 2 is a controller chip for executing computation, etc., in accordance with a command described in a software program. Therefore, in the following explanation, the first module 11 is called “a processor module 11”. Moreover, the first semiconductor chip 53 is called “a controller chip 53”.

As shown in FIG. 2, when the processor module 11 as a first module is mounted on the chassis 10 as a support member, the power supply submodule 51 included in the processor module 11 is connected to the electric connector 24 included in the chassis 10. Moreover, the passage 45 included in the processor module 11 is connected to the passage 30 included in the chassis 10. Besides, a plurality of optical submodules 52 included in the processor module 11 are connected to a plurality of optical connectors 25 included in the chassis 10. More details will be described hereafter.

While a lot of connect pins are provided in the power supply submodule 51 included in the processor module 11, a plurality of connecting holes are provided in the electric connector 24 included in the chassis 10. When the processor module 11 is mounted on the mounting surface 10b of the chassis 10, the connect pins protruded from the power supply submodule 51 are inserted in the connecting holes of the electric connector 24 so that both of them are connected to each other. As a result, electric power can be supplied to the processor module 11. Moreover, signals can be inputted to the processor module 11, and signals can be outputted from the processor module 11. Note that signals inputted in and outputted from the processor module 11 include control signals and other signals in addition to data signals.

Moreover, when the processor module 11 is mounted on the mounting surface 10b of the chassis 10, the pipe joint 46b protruded from the left side wall 42 of the first metal package 41 is inserted in the mouth ring 31a included in the chassis 10, and the first perpendicular passage 46 is connected to the feed passage 30a. At the same time, the pipe joint 47b protruded from the right side wall 43 of the first metal package 41 is inserted into the mouth ring 31b provided in the chassis 10, and the second perpendicular passage 47 is connected to the return passage 30b. As a result, the cooling water can be supplied to the processor module 11, and the cooling water can be collected from the processor module 11. That is, the cooling water can be circulated in the processor module 11. The circulating cooling water in the processor module 11 cools down the first package substrate 50 thermally connected to the first metal package 41 via the first metal package 41. Moreover, the cooling water also cools down the controller chip 53 equipped on the first package substrate 50 and the power supply submodule 51 and the optical submodule 52 mounted on the first package substrate 50. Therefore, it is preferred to form the first metal package 41 by a metallic material with excellent thermal conductivity, and, for example, aluminum and copper are preferable as the material of the first metal package 41. Note that a water shutoff valve 56 is fitted into each of the connecting hole 46a of the first perpendicular passage 46 and the connecting hole 47a of the second perpendicular passage 47.

Besides, when the processor module 11 is mounted on the mounting surface 10b of the chassis 10, a corresponding optical connector 25 is inserted into an insertion inlet included in each optical submodule 52. Each optical submodule 52 is provided with a light emitting element and a light receiving element, and each optical submodule 52 converts the optical signals inputted from the optical signal cable 23 into the electric signals and outputs the signals to the controller chip 53, while each optical submodule 52 converts the electric signals inputted from the controller chip 53 into the optical signals and outputs the signals to the optical signal cable 23. That is, each optical submodule 52 performs photoelectric conversion between the optical signal cable 23 and the controller chip 53. As the light emitting element included in the optical submodule 52, for example, a Vertical Cavity Surface Emitting LASER (VCSEL) is used. Moreover, as the light receiving element included in the optical submodule 52, for example, a photodiode (PD) is used. Each optical submodule 52 also includes a drive IC for driving the light emitting element and an amplification IC for amplifying electric signals outputted from the light receiving element. These drive IC and amplification IC are equipped on the substrate on which the light emitting element and the light receiving element are to be equipped, and are connected with the light emitting element or the light receiving element via a bonding wire. Besides, each optical submodule 52 has a lens block for making the optical signals emitted from the light emitting element incident on the optical signal cable 23 or making the optical signals emitted from the optical signal cable 23 on the light receiving element. A guide pin inserted in a positioning hole formed on an end surface of the optical connector 25 protrudes from an end surface of the lens block.

Moreover, when the processor module 11 is mounted on the mounting surface 10b of the chassis 10, the through bore 55 (FIG. 3) provided in the processor module 11 and the through bore 32 (FIG. 3) provided in the chassis 10 communicate with each other. The chassis 10 and the processor module 11 are fixed with each other with a bolt not shown but inserted in the communicated through bores 32 and 55.

As described above, when the processor module 11 is mounted on the chassis 10, the power supply submodule 51 is connected to the electric connector 24, the passage 45 is connected to the passage 30, and the optical submodule 52 is connected to the optical connector 25. Accordingly, the signals can be transmitted and received between a plurality of processor modules 11 mounted on the chassis 10. Moreover, the signals also can be transmitted and received between each processor module 11 and an external module/device.

Here, the signal transmission between the controller chip 53 and the optical submodule 52 in each processor module 11 is mostly performed via a wiring formed on the first package substrate 50. Moreover, the signal transmission between the plurality of processor modules 11 mounted on the chassis 10 is performed via the optical signal cable 23.

That is, in the multimodule 1A according to the present embodiment, the transmission of the high-speed digital signals is not performed via the mother board, but the transmission of the high-speed digital signals is performed via the first package substrate 50 or the optical signal cable (optical fiber) 23 with the transmission loss which is extremely less than that of the mother board. Therefore, the degradation of high-speed digital signals is suppressed, so that the compensating circuit is unnecessary, or the number of required compensating circuits decreases. Moreover, the chassis 10 and a plurality of first metal packages 41 are thermally connected, and the controller chip 53 equipped on the first package substrate 50 and the other heating bodies are cooled down (by water). Besides, a plurality of processor modules 11 are mounted on one chassis 10. That is, a plurality of modules are densely arranged in a small space.

Note that the first semiconductor chip is not limited to the controller chip 53. For example, in another embodiment, the first semiconductor chip included in one of the plurality of first modules 11 shown in FIG. 1A and FIG. 1B is a controller chip, and the first semiconductor chip included in the other first modules 11 is a memory chip, a switch chip, a router chip, or another semiconductor chip. In this case, the multimodule 1A can be functioned as a server, network equipment, etc. Moreover, the memory chip, the switch chip, the router chip, and the other semiconductor chip included in each first module 11 are centrally controlled by the controller chip included in the main first module 11. That is, one of the plurality of first modules 11 centrally controls the rest of the first modules 11. Moreover, a function and a capacity can be easily reduced or expanded by suitably increasing or decreasing the number and type of the first module 11.

### Second Embodiment

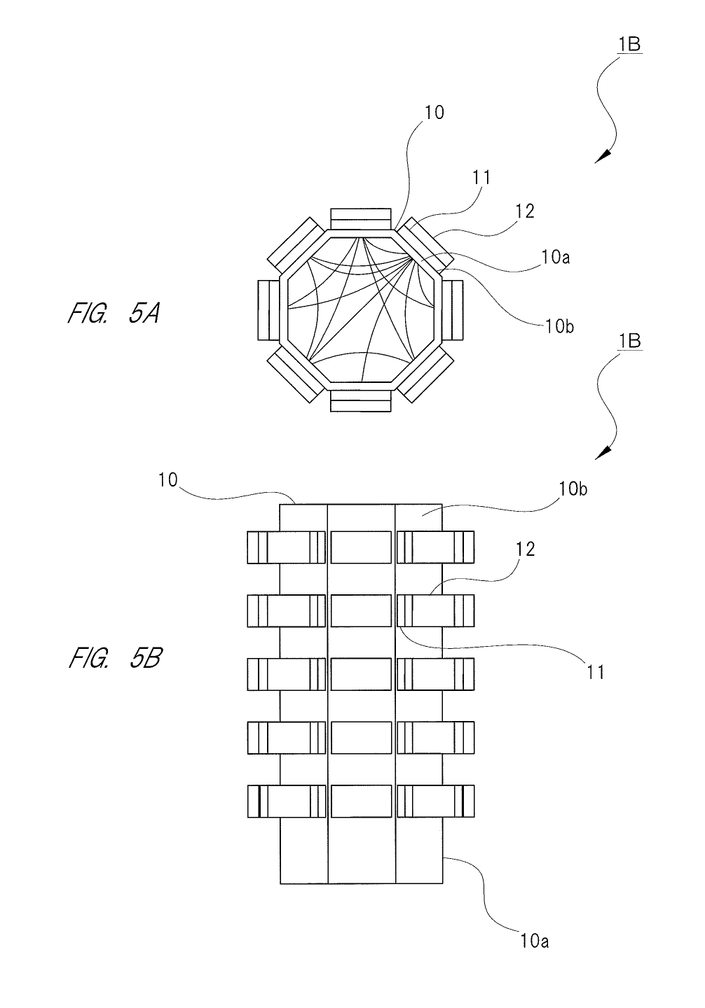

Hereafter, another example of the embodiment of the present invention will be described in detail with reference to FIGS. 5 to 7. Of course, the multimodule according to the present embodiment has a basic structure which is in common with the multimodule according to the first embodiment. Therefore, different points from the multimodule according to the first embodiment will be mainly described. Moreover, for the configuration which is in common with the multimodule according to the first embodiment, the same reference numbers are added in the drawing, and description thereof is suitably omitted.

In a multimodule 1B shown in FIG. 5, five first modules (processor modules) 11 are mounted on each mounting surface 10b of the chassis 10 along the longitudinal direction (height direction), and a second module 12 is mounted so as to be overlaid on each processor module 11.

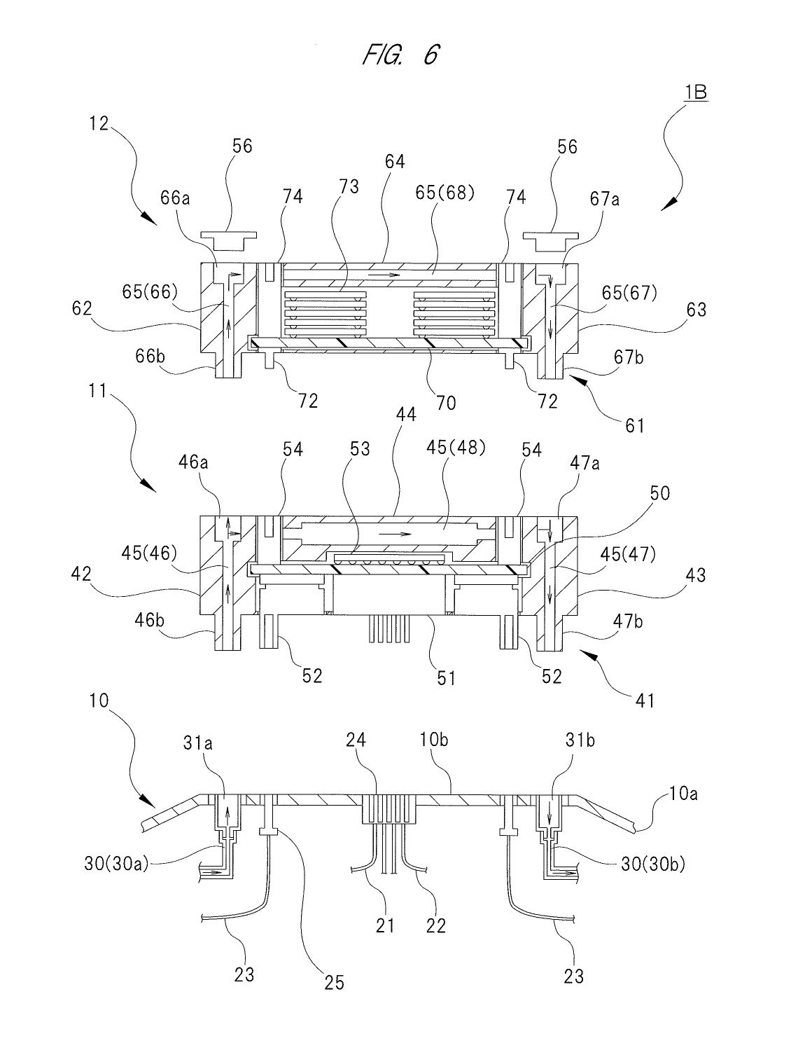

As shown in FIG. 6, the second module 12 includes a second package 61 having the substantially same appearance shape as the first metal package 41. The second package 61 according to the present embodiment is made of metal. Therefore, in the following explanation, the second package 61 is called “a second metal package 61”.

The second metal package 61 is formed in a predetermined shape by a die casting method or a cutting method, and has a left side wall 62, a right side wall 63, and a ceiling 64. A continued passage 65 is formed inside the left side wall 62, the right side wall 63, and the ceiling 64. Specifically, a third perpendicular passage 66 penetrating through the left side wall 62 is formed inside the left side wall 62, a fourth perpendicular passage 67 penetrating through the right side wall 63 is formed inside the right side wall 63, and a second horizontal passage 68 penetrating through the ceiling 64 is formed inside the ceiling 64. One end of the third perpendicular passage 66 is expanded in diameter to forma connecting hole 66a that is opened on an upper end surface of the left side wall 62, and the other end of the third perpendicular passage 66 is protruded from a lower end surface of the left side wall 62 to form a pipe joint 66b. Moreover, one end of the fourth perpendicular passage 67 is expanded in diameter to form a connecting hole 67a that is opened on an upper end surface of the right side wall 63, and the other end of the fourth perpendicular passage 67 is protruded from a lower end surface of the right side wall 63 to form a pipe joint 67b. Besides, one end of the second horizontal passage 68 is opened on one side surface of the ceiling 64, and the other end thereof is opened on the other side surface of the ceiling 64. In addition, the third perpendicular passage 66 and the fourth perpendicular passage 67 are connected via the second horizontal passage 68 to communicate with each other. That is, the continued passages 65 is formed inside the second metal package 61 by using the third perpendicular passage 66, the fourth perpendicular passage 67, and the second horizontal passage 68.

A second package substrate 70 is accommodated inside the second metal package 61. The second metal package 61 and the second package substrate 70 are physically in contact with each other, and both of them are thermally connected to each other. Specifically, a peripheral edge portion of the second package substrate 70 is fitted into a retention groove formed on the inner surface of the second metal package 61. A pair of second electric connectors (plug connector) 72 are mounted on one surface (lower surface) of the second package substrate 70 accommodated in the second metal package 61. On the other hand, a plurality of second semiconductor chips 73 are three-dimensionally mounted on the other surface (upper surface) of the second package substrate 70, and a pair of third electric connectors (receptacle connector) 74 are mounted on both sides of these second semiconductor chips 73. The second semiconductor chip 73 and the plug connector 72, and the second semiconductor chip 73 and the receptacle connector 74 are electrically connected via wiring or/and a through hole formed on the second package substrate 70. Moreover, a plurality of second semiconductor chips 73 are also electrically connected to each other if needed.

The same slit as the slit 44a shown in FIG. 3 is formed on the ceiling 64 of the second metal package 61, and the receptacle connector 74 is exposed on an upper surface of the second module 12. Moreover, the second horizontal passage 68 formed in the ceiling 64 of the second metal package 61 winds so as to avoid the receptacle connector 74 as similar to the first horizontal passage 48 shown in FIG. 3, and communicates the third perpendicular passage 66 to the fourth perpendicular passage 67. Besides, a through bore penetrating through the second metal package 61 is formed at each of four corners of the second metal package 61.

Here, the second semiconductor chip 73 shown in FIG. 6 is a memory chip. Specifically, the second semiconductor chip 73 is a volatile memory chip (DRAM/Dynamic Random Access Memory). Therefore, in the following explanation, the second module 12 is called “a memory module 12”. Moreover, the second semiconductor chip 73 is called “a memory chip 73”.

As shown in FIG. 6, when the memory module 12 is mounted so as to be overlaid on the processor module 11, the plug connector 72 included in the memory module 12 is connected to the receptacle connector 54 included in the processor module 11. Similarly, the passage 65 included in the memory module 12 is connected to the passage 45 included in the processor module 11. More details will be described below.

When the memory module 12 is mounted so as to be overlaid on the processor module 11, the plug connector 72 is inserted in the receptacle connector 54, and both connectors 72 and 54 are connected. As a result, the first package substrate 50 and the second package substrate 70 are electrically connected, so that the electric power can be supplied from the processor module 11 to the memory module 12. Besides, based on control of the controller chip 53, the data and program can be written in the memory chip 73, and the data and program can be read from the memory chip 73.

Moreover, when the memory module 12 is mounted over the processor module 11, the pipe joint 66b protruded from the left side wall 62 of the second metal package 61 is inserted in the connecting hole 46a which is opened on the left side wall 42 of the first metal package 41, and the third perpendicular passage 66 is connected to the first perpendicular passage 46. At the same time, the pipe joint 67b protruded from the right side wall 63 of the second metal package 61 is inserted in the connecting hole 47a which is opened on the right side wall 43 of the first metal package 41, and the fourth perpendicular passage 67 is connected to the second perpendicular passage 47. As a result, the cooling water can be supplied to the memory module 12, and the cooling water can be collected from the memory module 12. That is, the cooling water can be circulated in the memory module 12. The circulating cooling water in the memory module 12 cools down the second package substrate 70 thermally connected with the second metal package 61 via the second metal package 61 and the memory chip 73 equipped on the second package substrate 70. Note that a water shutoff valve 56 shown in FIG. 2 is fitted into the connecting hole 66a of the third perpendicular passage 66 and into the connecting hole 67a of the fourth perpendicular passage 67.

Moreover, when the memory module 12 is mounted on the processor module 11, a through bore (not shown) provided in the memory module 12 and the through bore 55 (FIG. 3) provided in the processor module 11 communicate with each other.

As described above, when the processor module 11 is mounted on the chassis 10, the power supply submodule 51 is connected to the electric connector 24, the passage 45 is connected to the passage 30, and the optical submodule 52 is connected to the optical connector 25. Moreover, when the memory module 12 is mounted so as to be overlaid on the processor module 11, the plug connector 72 is connected to the receptacle connector 54, and the passage 65 is connected to the passage 45. That is, the processor module 11 is connected to the chassis 10, and the memory module 12 is connected to the processor module 11 connected to the chassis 10. In other words, a plurality of modules (the processor module 11 and the memory module 12) are connected in multi-stages. And, the signals can be transmitted and received between the processor module 11 and the memory module 12. That is, the signals can be transmitted and received (inputted and outputted) inside a group of modules connected in multi-stages. Moreover, the signals can be transmitted and received between a group of modules connected in multi-stages and another group of modules. Besides, the signals can be transmitted and received between a group of modules connected in multi-stages and an external device.

Note that the overlaid chassis 10, processor module 11, and memory module 12 as described above are fixed with a bolt not show but inserted in the through bore 32 (FIG. 3) of the chassis 10, the through bore 55 (FIG. 3) of the processor module 11 and a through bore (not shown) of the memory module which communicate with each other.

Here, the transmission of signals between the controller chip 53 and the optical submodule 52 inside the processor module 11 is performed mostly via the wiring formed in the first package substrate 50. Moreover, the transmission of signals between the controller chip 53 included in the processor module 11 and the memory chip 73 included in the memory module 12 is performed mostly via the first package substrate 50 and the second package substrate 70. That is, the transmission of the high-speed digital signals is not performed via the mother board, but the transmission of the high-speed digital signals is performed via a package substrate with transmission loss which is extremely less than that of the mother board. Therefore, the degradation of the high-speed digital signals is suppressed, a compensating circuit is unnecessary, or the number of required compensating circuits decreases. Moreover, the chassis 10, a plurality of first metal packages 41, and a plurality of second metal packages 61 are thermally connected with each other, and the controller chip 53 equipped on the first package substrate 50, the memory chip 73 equipped on the second package substrate 70, and other heating body are cooled down (by water). Besides, a plurality of processor module 11 and memory module 12 are mounted on one chassis 10. That is, a plurality of modules are densely arranged in a small space.

It is clear that the multimodule 1B according to the present embodiment can be functioned as a server, network equipment, etc. as similar to the multimodule 1A according to the first embodiment. Moreover, easy expansion or reduction of the function and the capacity by suitably increasing or decreasing the number and type of the first module 11 or the second module 12 is also similar to the multimodule 1A.

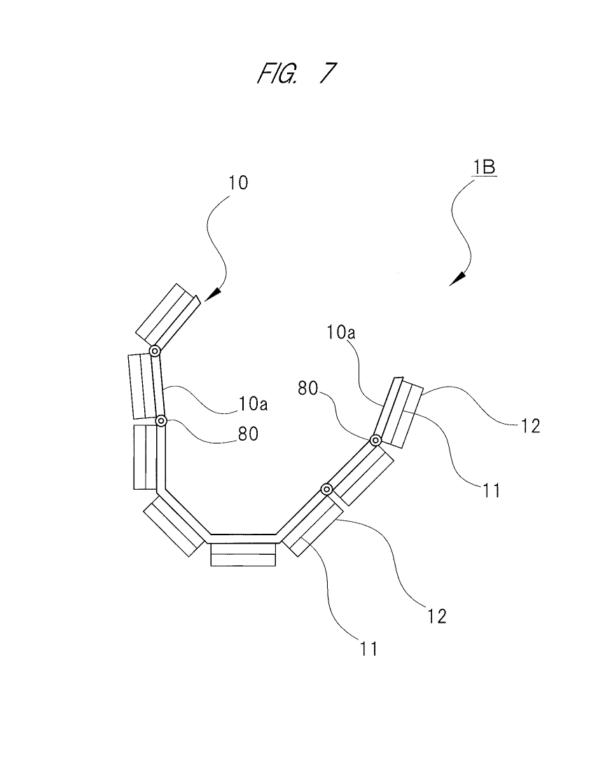

As shown in FIG. 7, some of the side walls 10a of the chassis 10 are coupled by a hinge 80 so as to freely rotate. That is, the chassis 10 can be expanded. The chassis 10 is expanded in assembly work or maintenance work inside the chassis 10. The assembly work inside the chassis 10 is, for example, wiring work of the power cable 21 and the optical signal cable 23 shown in FIG. 6, and setting work of a power unit and a cooling device, etc. Note that the chassis 10 shown in FIG. 1 can be also expanded as similar to the chassis 10 shown in FIG. 7. Moreover, the shape of the chassis 10 is not limited to the octagon (polygon) but is any shape.

### Third Embodiment

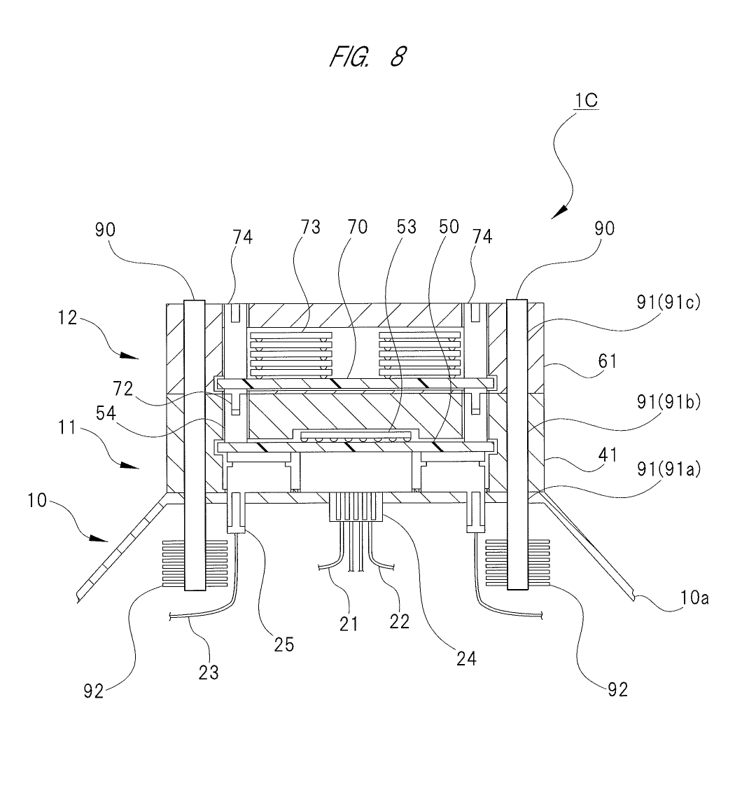

Hereafter, another example of the embodiment of the present invention will be described in detail with reference to FIG. 8. Of course, the multimodule according to the present embodiment has a basic structure which is in common with the multimodules according to the first and second embodiments. Therefore, different points from the multimodules according to the first and second embodiments will be mainly described. Moreover, for the configuration which is in common with the multimodules according to the first and second embodiments, the same reference numbers are added in FIG. 8, and description thereof is suitably omitted.

A multimodule 1C shown in FIG. 8 includes the chassis 10, the first module (processor module) 11, and the second module (memory module) 12. The processor module 11 is mounted on the chassis 10, and the memory module 12 is mounted so as to be overlaid on the processor module 11. The chassis 10, the processor module 11, and the memory module 12 have the same structure as those in the first and the second embodiments.

In the multimodule 1C shown in FIG. 8, a cylindrical heat conduction member 90 penetrates through the chassis 10, the processor module 11, and the memory module 12. Specifically, through bores 91a, 91b, and 91c are formed at each of four corners of the side wall 10a of the chassis 10, the first metal package 41, and the second metal package 61, respectively. When the processor module 11 is mounted on each side wall 10a of the chassis 10, and when the memory module 12 is mounted on the processor module 11, the through bores 91a, 91b, and 91c communicate with each other. That is, a plurality of the through bores 91 penetrating through the chassis 10, the processor module 11, and the memory module 12 are formed. The heat conduction member 90 is inserted in each of the through bores 91 formed as described above.

A plurality of heat-radiating fins 92 are provided in at least apart of the heat conduction members 90. In the present embodiment, a heat-radiating fin 92 is provided below the heat conduction member 90 positioned inside the chassis 10. The heat emitted from the processor module 11 and the memory module 12 is conducted to the heat-radiating fin 92 via the heat conduction member 90, and is released from a surface of the heat-radiating fin 92 to the air. That is, in the present embodiment, the processor module 11 and the memory module 12 are cooled by air. Note that natural convection inside the chassis is acceptable. However, in a high performance device, forced air cooling with a fan is preferred. Moreover, the heat conduction member 90 is preferably a heat pipe. Moreover, the heat conduction member 90 is also functioned as a fixing member which fixes the chassis 10, the processor module 11, and the memory module 12 with each other. Of course, the chassis 10, the processor module 11, and the memory module 12 can be also fixed with each other with a different fixing member from the heat conduction member 90.

### Fourth Embodiment

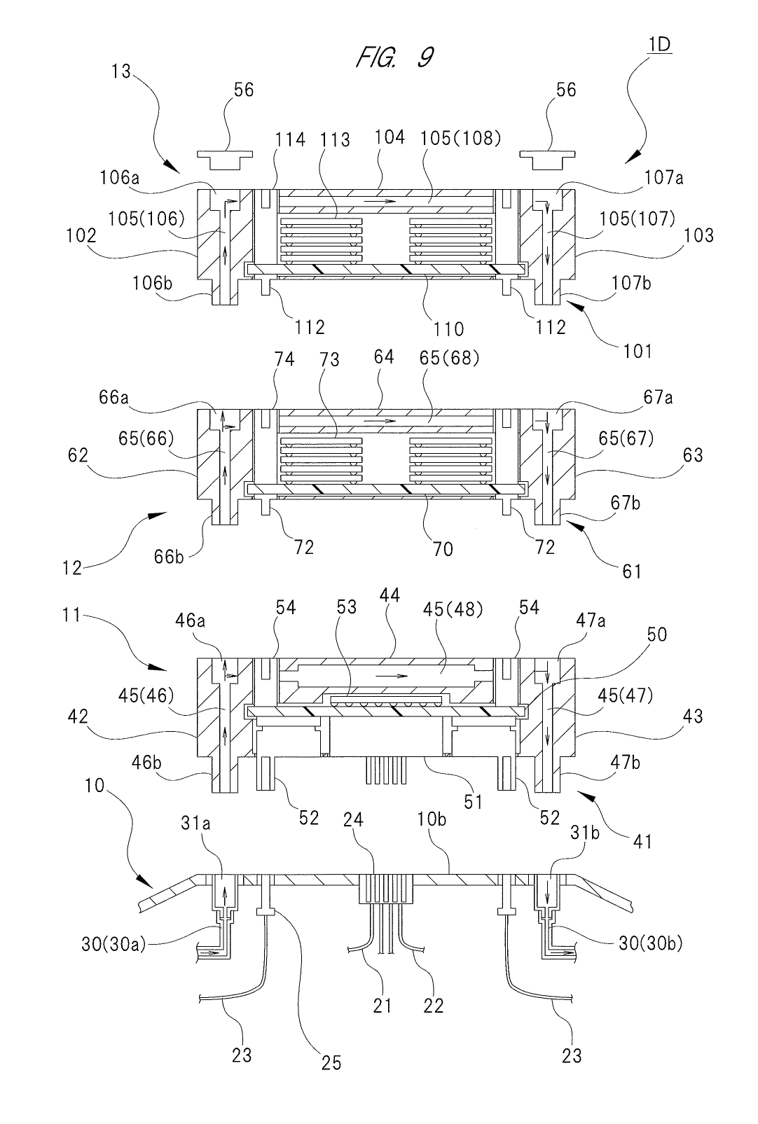

Hereafter, another example of the embodiment of the present invention will be described in detail with reference to FIG. 9. Of course, the multimodule according to the present embodiment has a basic structure which is in common with the multimodules according to the first to third embodiments. Therefore, different points from the multimodules according to the first to third embodiments will be mainly described. Moreover, for the configuration which is in common with the multimodules according to the first to third embodiments, the same reference numbers are added in FIG. 9, and description thereof is suitably omitted.

A multimodule 1D shown in FIG. 9 includes the chassis 10, the first module (processor module) 11, the second module (memory module) 12, and a third module 13. The processor module 11 is mounted on the chassis 10, the memory module 12 is mounted so as to be overlaid on the processor module 11, and the third module 13 is mounted so as to be overlaid on the memory module 12. The chassis 10, the processor module 11, and the memory module 12 have the same basic structure as those in the first to three embodiments.

The third module 13 includes a third package 101 having the substantially same appearance shape as those of the first metal package 41 and the second metal package 61. The third package 101 in the present embodiment is made of metal. Therefore, in the following explanation, the third package 101 is called “a third metal package 101”.

The third metal package 101 has a left side wall 102, a right side wall 103, and a ceiling 104. A continued passage 105 is formed inside the left side wall 102, the right side wall 103, and the ceiling 104. Specifically, a fifth perpendicular passage 106 penetrating through the left side wall 102 is formed inside the left side wall 102, a sixth perpendicular passage 107 penetrating through the right side wall 103 is formed inside the right side wall 103, and a third horizontal passage 108 penetrating through the ceiling 104 is formed inside the ceiling 104. One end of the fifth perpendicular passage 106 is expanded in diameter to form a connecting hole 106a that is opened on an upper end surface of the left side wall 102, and the other end of the fifth perpendicular passage 106 is protruded from a lower end surface of the left side wall 102 to form a pipe joint 106b. Moreover, one end of the sixth perpendicular passage 107 is expanded in diameter to form a connecting hole 107a that is opened on an upper end surface of the right side wall 103, and the other end of the sixth perpendicular passage 107 is protruded from a lower end surface of the right side wall 103 to form a pipe joint 107b. Besides, one end of the third horizontal passage 108 is opened on one side surface of the ceiling 104, and the other end thereof is opened on the other side surface of the ceiling 104. In addition, the fifth perpendicular passage 106 and the sixth perpendicular passage 107 are connected via the third horizontal passage 108 to communicate with each other. That is, the continued passages 105 is formed inside the third metal package 101 by using the fifth perpendicular passage 106, the sixth perpendicular passage 107, and the third horizontal passage 108.

A third package substrate 110 is accommodated inside the third metal package 101. The third metal package 101 and the third package substrate 110 are physically in contact with each other, and both of them are thermally connected to each other. Specifically, a peripheral edge portion of the third package substrate 110 is fitted into a retention groove formed on the inner surface of the third metal package 101. A pair of fourth electric connectors (plug connector) 112 are mounted on one surface (lower surface) of the third package substrate 110. On the other hand, a plurality of third semiconductor chips 113 are three-dimensionally mounted on the other surface (upper surface) of the third package substrate 110, and a pair of fifth electric connectors (receptacle connector) 114 are mounted on both sides of these third semiconductor chips 113. The third semiconductor chip 113 and the plug connector 112, and the third semiconductor chip 113 and the receptacle connector 114 are electrically connected via a wiring or/and a through hole formed on the third package substrate 110. Moreover, a plurality of third semiconductor chips 113 are also electrically connected to each other if needed.

The same slit as the slit 44a shown in FIG. 3 is formed on the ceiling 104 of the third metal package 101, and the receptacle connector 114 is exposed on an upper surface of the third module 13. Moreover, the third horizontal passage 108 formed in the ceiling 104 of the third metal package 101 winds so as to avoid the receptacle connector 114 as similar to the first horizontal passage 48 shown in FIG. 3, and communicates the fifth perpendicular passage 106 to the sixth perpendicular passage 107. Besides, a through bore not shown is formed at each of four corners of the third metal package 101.

Here, the third semiconductor chip 113 shown in FIG. 9 is a memory chip. Specifically, the third semiconductor chip 113 is a nonvolatile memory chip (for example, flash memory). Therefore, in the following explanation, the third module 13 is called “a storage module 13”. Moreover, the third semiconductor chip 113 is called “a memory chip 113”.

As shown in FIG. 9, when the storage module 13 is mounted so as to be overlaid on the memory module 12, the plug connector 112 included in the storage module 13 is connected to the receptacle connector 74 included in the memory module 12. Similarly, the passage 105 included in the storage module 13 is connected to the passage 65 included in the memory module 12. More details will be described below.

When the storage module 13 is mounted so as to be overlaid on the memory module 12, the plug connector 112 is inserted in the receptacle connector 74, and both connectors 112 and 74 are connected. As a result, the first package substrate 50, the second package substrate 70, and the third package substrate 110 are electrically connected, so that the electric power can be supplied from the processor module 11 to the storage module 13. Besides, based on control of the controller chip 53, the data and program can be written in the memory chip 113, and the data and program can be read from the memory chip 113.

Moreover, when the storage module 13 is mounted so as to be overlaid on the memory module 12, the pipe joint 106b protruded from the left side wall 102 of the third metal package 101 is inserted in the connecting hole 66a which is opened on the left side wall 62 of the second metal package 61, and the fifth perpendicular passage 106 is connected to the third perpendicular passage 66. At the same time, the pipe joint 107b protruded from the right side wall 103 of the third metal package 101 is inserted in the connecting hole 67a which is opened on the right side wall 63 of the second metal package 61, and the sixth perpendicular passage 107 is connected to the fourth perpendicular passage 67. As a result, the cooling water can be supplied to the storage module 13, and the cooling water can be collected from the storage module 13. That is, the cooling water can be circulated in the storage module 13. The circulating cooling water in the storage module 13 cools down the third package substrate 110 thermally connected with the third metal package 101 via the third metal package 101 and the memory chip 113 equipped on the third package substrate 110. Note that a water shutoff valve 56 shown in FIG. 6 is fitted into each of the connecting hole 106a of the fifth perpendicular passage 106 and the connecting hole 107a of the sixth perpendicular passage 107.

A multimodule 1D according to the present embodiment includes the processor module 11, the memory module 12 mounted so as to be overlaid on the processor module 11, and a storage module 13 mounted so as to be overlaid on the memory module 12. The memory module 12 is provided with a volatile memory chip, and the storage module 13 is provided with a nonvolatile memory chip. Therefore, the multimodule 1D can be functioned as a server, network equipment, a computer, etc. Moreover, the function and the capacity can be easily expanded or reduced by suitably increasing or decreasing the numbers and types of the first module 11, the second module 12, and the third module 13.

Here, the transmission of signals between the controller chip 53 included in the processor module 11, the memory chip 73 included in the memory module 12, and a memory chip 113 included in the storage module 13 is performed mostly via the first package substrate 50, the second package substrate 70, and third package substrate 110. That is, the transmission of the high-speed digital signals is not performed via the mother board, but the transmission of the high-speed digital signals is performed via the package substrate with transmission loss which is extremely lower than that of the mother board. Therefore, the degradation of the high-speed digital signals is suppressed, a compensating circuit is unnecessary, or the number of the required compensating circuit decreases. Moreover, the chassis 10, a plurality of first metal packages 41, a plurality of second metal packages 61, and a plurality of third metal packages 101 are thermally connected, and the controller chip 53 equipped on the first package substrate 50, the memory chip 73 equipped on the second package substrate 70, the memory chip 113 equipped on the third package substrate 110, and other heating bodies are cooled down (by water). Besides, a plurality of the processor module 11, the memory module 12, and the storage module 13 are mounted on one chassis 10. That is, a plurality of modules are densely arranged in a small space.

The present invention is not limited to the above-described embodiments, and can be variously changed within the scope of the present invention. For example, the first package 41, the second package 61, and the third package 101 are not limited to being made of metal.

Moreover, the controller chip 53 as a first semiconductor chip, the memory chip 73 as a second semiconductor chip, and the memory chip 113 as a third semiconductor chip can be replaceable by each other. For example, the first semiconductor chip (controller chip) 53 included in the first module 11 shown in FIG. 1 and the second semiconductor chip (memory chip) 73 included in the second module 12 are replaceable by each other. In this case, the first module 11 becomes the memory module, and the second module 12 becomes the processor module. Besides, the optical submodule 52 shown in FIG. 6 is changed so as to be set in the second module 12, and an optical transmission line is provided inside the first module 11 for passing the optical signals between the optical signal cable 23 and the optical submodule 52 changed so as to be set in the second module 12. Of course, when a lamination distance between the first module 11 and the second module 12 is small (for example, 5 cm or shorter), or when a transmission rate of signals is low (for example, 25 Gbit/sec or later), the optical submodule 52 may be arranged in the first module 11.

What is claimed is:

1. A multimodule comprising:
a support member to which a power cable and an optical signal cable are drawn; and
a plurality of first modules which are mounted on the support member and to which the power cable and the optical signal cable are connected,
wherein each of the first modules includes: a first package; a first package substrate accommodated in the first package; and a first semiconductor chip equipped on the first package substrate.

2. The multimodule according to claim 1, comprising:
a plurality of second modules mounted so as to be overlaid on each of the first modules,
wherein each of the second modules includes: a second package; a second package substrate accommodated in the second package; and a second semiconductor chip equipped on the second package substrate.

3. The multimodule according to claim 2,
wherein the first package and the second package are made of metal, and are thermally connected to each other,
the first package and the first package substrate accommodated in the first package are thermally connected to each other, and
the second package and the second package substrate accommodated in the second package are thermally connected to each other.

4. The multimodule according to claim 2,
wherein the first package substrate accommodated in the first package and the second package substrate accommodated in the second package are electrically connected to each other.

5. The multimodule according to claim 2,
wherein each of the first modules includes: a power supply submodule and an optical submodule mounted on one surface of the first package substrate; a controller chip as the first semiconductor chip equipped on the other surface of the first package substrate; and a first electric connector arranged on the other surface of the first package substrate,
each of the second modules includes: a second electric connector arranged on one surface of the second package substrate; and a memory chip as the second semiconductor chip equipped on the other surface of the second package substrate,
in the first module, the optical submodule and the controller chip, and the first electric connector and the controller chip are connected to each other via a wiring formed in the first package substrate,
in the second module, the memory chip and the second electric connector are connected to each other via a wiring formed in the second package substrate, and
the first module and the second module are connected to each other via the first electric connector and the second electric connector.

6. The multimodule according to claim 2,
wherein a passage is formed in each of the support member, the first package, and the second package for communicating with each other.

7. The multimodule according to claim 2, comprising:
a heat conduction member penetrating through the support member, the first package, and the second package,
wherein a heat-radiating fin is provided in at least a part of the heat conduction member.

8. The multimodule according to claim 2, comprising:
a third module mounted so as to be overlaid on the second module,
wherein the third module includes: a third package; a third package substrate accommodated in the third package; and a third semiconductor chip equipped on the third package substrate.

9. The multimodule according to claim 8,
wherein a volatile memory chip as the second semiconductor chip is equipped on the second package substrate of the second module, and
a nonvolatile memory chip as the third semiconductor chip is equipped on the third package substrate of the third module.

10. The multimodule according to claim 2,
wherein the support member includes a plurality of mounting portions on which the first module is mounted and which are connected to each other so as to freely rotate.
